(19) United States
(12) Patent Application Publication
(10) Pub. No.: US 2018/0358320 A1
(43) Pub. Date: Dec. 13, 2018

(54) ELECTRONIC DEVICE, ELECTRONIC DEVICE MANUFACTURING METHOD, AND ELECTRONIC APPARATUS

(71) Applicant: FUJITSU LIMITED, Kawasaki-shi (JP)

(72) Inventors: Kimio Nakamura, Suzaka (JP); NAOKI ISHIKAWA, Nagano (JP); Hiroshi Kobayashi, Kawasaki (JP); Shuichi Takeuchi, Chikuma (JP)

(73) Assignee: FUJITSU LIMITED, Kawasaki-shi (JP)

(21) Appl. No.: 15/996,744

(22) Filed: Jun. 4, 2018

(30) Foreign Application Priority Data
Jun. 7, 2017 (JP) 2017-112759

(51) Int. Cl. H01L 23/00

(52) U.S. Cl. CPC H01L 24/73; H01L 2224/81205; H01L 24/32; H01L 24/81; H01L 24/83; H01L 24/92; H01L 2224/16227; H01L 2224/32225; H01L 2224/73204; H01L 2224/81208; H01L 2224/83208; H01L 2224/9211; H01L 2224/81191; H01L 2224/83192; H01L 2224/83862; H01L 2224/13144; H01L 2224/05647; H01L 2224/05624; H01L 24/05; H01L 2224/0401; H01L 2224/2919; H01L 2924/3511; H01L 2224/8183; H01L 24/16

(57) ABSTRACT

An electronic device includes a first electronic part that includes a first terminal, a second electronic part disposed to be opposed to the first electronic part, the second electronic part that includes a second terminal including a first end part in contact with the first terminal and a second end part located on an outside of the first terminal, and an adhesive disposed between the first electronic part and the second electronic part, the adhesive maintaining the contact between the first terminal and the first end part by bonding the first electronic part and the second electronic part to each other.

### CROSS-REFERENCE TO RELATED APPLICATION

This application is based upon and claims the benefit of priority of the prior Japanese Patent Application No. 2017-112759, filed on Jun. 7, 2017, the entire contents of which are incorporated herein by reference.

### FIELD

The embodiments discussed herein are related to an electronic device, an electronic device manufacturing method, and an electronic apparatus.

### BACKGROUND

As one of electronic part mounting technologies, there is a method referred to as a pressure contact method, a Flip Chip Attach (FCA) method, or the like. For example, there is a technology in which a semiconductor chip is disposed on a wiring board provided with an adhesive, a bump electrode of the semiconductor chip is coupled to an electrode pad of the wiring board, the adhesive is cured in that state, and the bump electrode and the electrode pad are brought into pressure contact with each other by a compressive force occurring in the cured adhesive.

In an electronic device obtained by the mounting technology as described above, when a sufficient load is not applied between the bump electrode of the semiconductor chip and the electrode pad of the wiring board, the bump electrode and the electrode pad being coupled to each other, an increase in resistance or a failure in coupling may occur, and there is thus a fear of inviting a decrease in coupling quality and coupling reliability of the bump electrode of the semiconductor chip and the electrode pad of the wiring board. The decrease in coupling quality and coupling reliability, the decrease being caused by such a load, may similarly occur in coupling between terminals of various kinds of electronic parts as well as the coupling between the bump electrode of the semiconductor chip and the electrode pad of the wiring board.

The following is a reference document.

### [Document 1] Japanese Laid-open Patent Publication No. 10-270496.

### SUMMARY

According to an aspect of the invention, an electronic device includes a first electronic part that includes a first terminal, a second electronic part disposed to be opposed to the first electronic part, the second electronic part that includes a second terminal including a first end part in contact with the first terminal and a second end part located on an outside of the first terminal, and an adhesive disposed between the first electronic part and the second electronic part, the adhesive maintaining the contact between the first terminal and the first end part by bonding the first electronic part and the second electronic part to each other.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are diagrams of assistance in explaining a pressure contact method;

FIG. 2 is a diagram of assistance in explaining a joining mechanism of a pressure contact method;

FIG. 3 is a diagram of assistance in explaining a phenomenon that occurs in a pressure contact method;

FIGS. 4A and 4B are diagrams of assistance in explaining another example of a pressure contact method;

FIGS. 5A and 5B are diagrams illustrating an example of an electronic device according to a first embodiment;

FIGS. 6A and 6B are diagrams illustrating an example of a method of forming an electronic device according to the first embodiment;

FIGS. 7A, 7B, and 7C are diagrams illustrating an example of an electronic device according to a second embodiment;

FIGS. 8A and 8B are diagrams illustrating an example of a method of forming an electronic device according to the second embodiment;

FIGS. 9A, 9B, and 9C are diagrams of assistance in explaining a result of analysis of stress in an electronic device according to the second embodiment;

FIGS. 10A, 10B, and 10C are diagrams illustrating an example of an electronic device according to a third embodiment;

FIGS. 11A, 11B, and 11C are diagrams illustrating an example of an electronic device according to a fourth embodiment;

FIGS. 12A, 12B, and 12C are diagrams illustrating an example of an electronic device according to a fifth embodiment;

FIGS. 13A and 13B are diagrams illustrating an example of an electronic device according to a sixth embodiment;

FIGS. 14A and 14B are diagrams illustrating an example of an electronic device according to a seventh embodiment; and

FIG. 15 is a diagram of assistance in explaining an electronic apparatus according to an eighth embodiment.

### DESCRIPTION OF EMBODIMENTS

Description will first be made of a pressure contact method as one of electronic part mounting technologies. In the following, mounting of a semiconductor chip (semiconductor element) onto a board by the pressure contact method will be taken as an example.

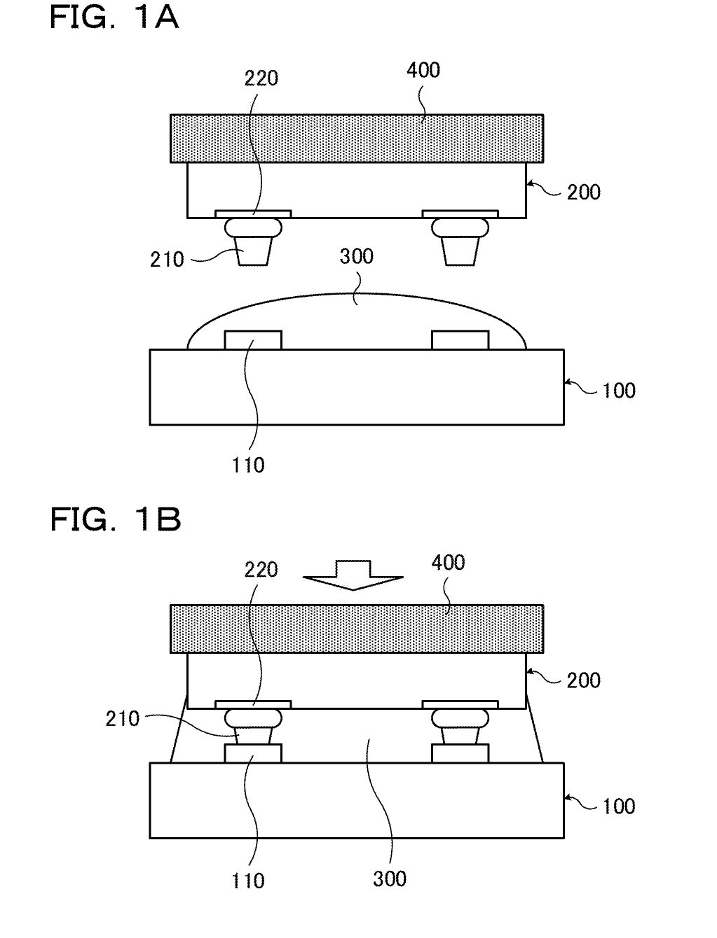

FIGS. 1A and 1B are diagrams of assistance in explaining a pressure contact method. FIG. 1A is a fragmentary sectional schematic view of a process of arranging a board and a semiconductor chip. FIG. 1B is a fragmentary sectional schematic view of a process of joining the board and the semiconductor chip to each other.

A substrate 100 and a semiconductor chip 200 as illustrated in FIG. 1A, for example, are prepared.

Used as the substrate 100 are various kinds of substrates such as a package substrate, a main substrate and an interposer, and various kinds of boards such as a rigid board and a flexible board. A surface of the substrate 100 or the surface and an inner layer of the substrate 100 are provided with a conductor portion such as wiring not illustrated, and the surface of the substrate 100 is provided with a pad 110 (terminal) coupled to such a conductor portion. Various kinds of conductor materials such as copper (Cu) and aluminum (Al) are used as the conductor portion and the pad 110 of the substrate 100.

The semiconductor chip 200 is internally provided with a circuit element such as a transistor not illustrated and a conductor portion such as wiring coupled to the circuit element. A surface of the semiconductor chip 200 is provided with an electrode 220 coupled to such a conductor portion. Various kinds of conductor materials such as Cu and Al are used as the conductor portion and the electrode 220 of the semiconductor chip 200. A bump 210 (terminal) is disposed on the electrode 220. A stud bump of gold (Au), for example, is used as the bump 210.

The pad 110 of the substrate 100 and the bump 210 of the semiconductor chip 200 are arranged at positions corresponding to each other.

When the semiconductor chip 200 is mounted on the substrate 100 by the pressure contact method, an adhesive 300 is provided on the substrate 100 in advance, as illustrated in FIG. 1A. A thermosetting resin or a thermosetting resin containing an inorganic or organic insulative filler, for example, is used as the adhesive 300. Not only a thermosetting resin but also a photocuring resin may be used as the adhesive 300. The adhesive 300 for which a given material is used is provided on the substrate 100 by a coating method or the like. Then, a bonding tool 400 is used, and the semiconductor chip 200 is disposed to be opposed to the substrate 100 above the substrate 100 provided with the adhesive 300, with the bump 210 of the semiconductor chip 200 aligned with the pad 110 of the substrate 100.

Next, as illustrated in FIG. 1B, the semiconductor chip 200 is pressurized and heated by the bonding tool 400, and thus the bump 210 of the semiconductor chip 200 is brought into pressure contact with the pad 110 of the substrate 100. In a case where a thermosetting resin is used as the adhesive 300, the adhesive 300 is cured by heating in a state in which the bump 210 is in pressure contact with the pad 110. In a case where a photocuring resin is used as the adhesive 300, the adhesive 300 is cured by irradiating the adhesive 300 with light in a state in which the bump 210 is in pressure contact with the pad 110. The cured adhesive 300 bonds the semiconductor chip 200 and the substrate 100 to each other, and maintains the contact between the pad 110 and the bump 210. The pressure contact method thus mechanically and electrically joins the substrate 100 and the semiconductor chip 200 to each other.

A mechanism of the joining of the substrate 100 and the semiconductor chip 200 to each other by the pressure contact method is considered to be as follows.

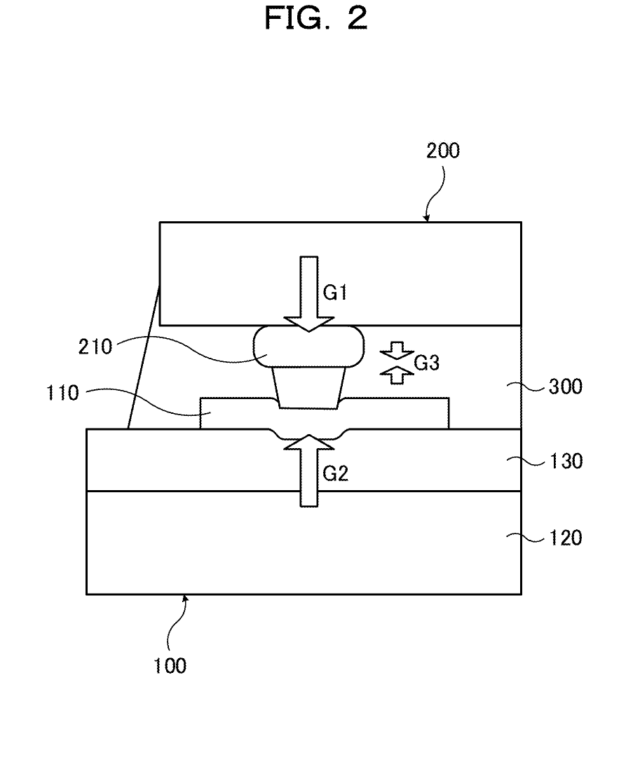

FIG. 2 is a diagram of assistance in explaining a joining mechanism of a pressure contact method. FIG. 2 is a fragmentary sectional schematic view of the substrate and the semiconductor chip joined to each other via the adhesive.

The substrate 100 illustrated in FIG. 2 includes a structure in which a core base material 120 is provided thereon with another base material 130, and the pad 110 is provided on the base material 130. Used as the base material 120 is a resin substrate, a resin substrate including glass fiber or the like, a glass substrate, a ceramic substrate, a semiconductor substrate, or the like. Used as the base material 130 is prepreg or the like.

For example, the semiconductor chip 200 is disposed on the substrate 100 as illustrated in FIG. 2 via the adhesive 300, as described above, and pressurization and heating are performed by a bonding tool (not illustrated). The pressurization and the heating bring the bump 210 in pressure contact with the pad 110, and cure the adhesive 300.

At this time, a load (bonding load) G1 at the time of the pressurization of the semiconductor chip 200 presses the bump 210 to the pad 110 side, and a reaction force G2 caused by pressing the pad 110 and the base material 130 presses the pad 110 to the bump 210 side. Thus, the pad 110 and the bump 210 are brought into contact with each other, and are brought into pressure contact with each other. Further, curing shrinkage occurs in the adhesive 300 that bonds the substrate 100 and the semiconductor chip 200 to each other, the curing shrinkage meaning that the adhesive 300 shrinks when cured. A compressive force G3 accompanying the curing shrinkage of the adhesive 300 maintains or reinforces the pressure contact between the pad 110 and the bump 210.

Thus, forces such as the bonding load G1, the reaction force G2, and the compressive force G3 act on the pad 110 and the bump 210 in contact with each other, and bring the pad 110 and the bump 210 into pressure contact with each other. In the following, forces acting on contact portions of the pad 110 and the bump 210 (load applied to the contact portions or stress occurring in the contact portions) will be referred to as a pressure contact force.

Incidentally, factors in decreasing such a pressure contact force include swelling of the adhesive 300 due to moisture absorption, a reduction in the curing shrinkage (compressive force G3 accompanying the curing shrinkage) due to a degradation of the adhesive 300, an effect of a warp resulting from a difference in thermal expansion coefficient between the substrate 100 and the semiconductor chip 200, and the like.

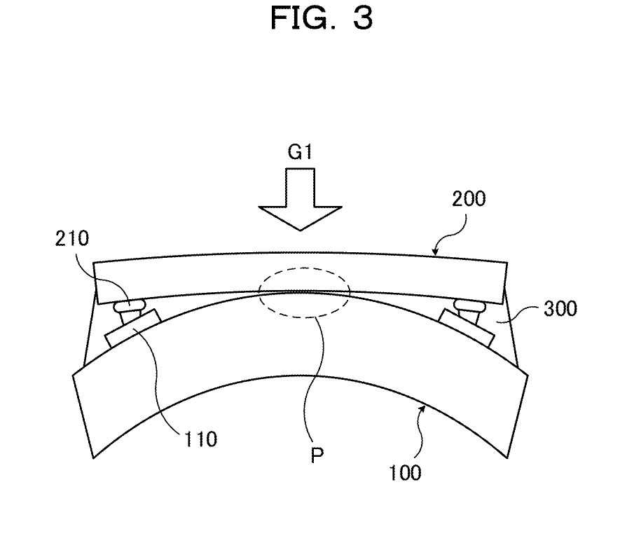

Increasing the pressure contact force acting on the contact portions of the pad 110 and the bump 210 is desirable from a viewpoint of enhancing coupling quality and coupling reliability by suppressing an increase in resistance or a failure in coupling between the pad 110 and the bump 210. One of methods of increasing the pressure contact force is a method of increasing the bonding load G1 when pressurizing the semiconductor chip 200 in the pressure contact method described above. However, depending on forms of the substrate 100 and the semiconductor chip 200, it may be difficult to increase the bonding load G1 at the time of the pressurization. This point will be described with reference to FIG. 3.

FIG. 3 is a diagram of assistance in explaining a phenomenon occurring in a pressure contact method. FIG. 3 is a fragmentary sectional schematic view of a process of joining the substrate and the semiconductor chip to each other.

When the adhesive 300 is disposed on the substrate 100, and the semiconductor chip 200 is pressurized and heated, the heating and subsequent cooling cause a warp in the substrate 100 and the semiconductor chip 200, as illustrated in FIG. 3. There is a difference in thermal expansion coefficient between the substrate 100 and the semiconductor chip 200, and a larger warp than that of the semiconductor chip 200, for example, a large warp approximately 50 times that of the semiconductor chip occurs in the substrate 100.

When a warp thus occurs in the substrate 100 and the semiconductor chip 200, a gap between the substrate 100 and the semiconductor chip 200 is narrowed depending on relation between amounts of warp of the substrate 100 and the semiconductor chip 200 and the size of the bump 210. Therefore, when the bonding load G1 is applied such that a pressure contact force satisfying given coupling quality and given coupling reliability acts on the pad 110 and the bump 210, there is a possibility of contact between the substrate 100 and the semiconductor chip 200 (circuit surfaces of the substrate 100 and the semiconductor chip 200), as in a P portion illustrated in FIG. 3. For example, contact between the substrate 100 and the semiconductor chip 200 may occur when the bonding load G1 is applied such that a pressure contact force satisfying a given reliability test such as a pressure cooker test (PCT), a highly accelerated stress test (HAST), or a temperature cycling test (TCT) acts on the pad 110 and the bump 210.

When the substrate 100 and the semiconductor chip 200 come into contact with each other, a circuit surface of the semiconductor chip 200 may be broken due to damage of the contact. In a case where the adhesive 300 contains a filler, the filler of the adhesive 300 collides with the circuit surface of the semiconductor chip 200 when the substrate 100 and the semiconductor chip 200 come into contact with each other, and the circuit surface of the semiconductor chip 200 may be broken due to damage of the collision.

Therefore, the bonding load G1 is limited to a range such that the semiconductor chip 200 does not come into contact with the substrate 100 or a range such that the filler of the adhesive 300 does not collide with the circuit surface of the semiconductor chip 200. When the bonding load G1 is limited to such a range, the pressure contact force between the pad 110 and the bump 210 becomes insufficient, and it becomes difficult to increase the pressure contact force between the pad 110 and the bump 210 by increasing the bonding load G1. As a result, an increase in resistance or a failure in coupling between the pad 110 and the bump 210 is incurred, so that high coupling quality and high coupling reliability may not be obtained.

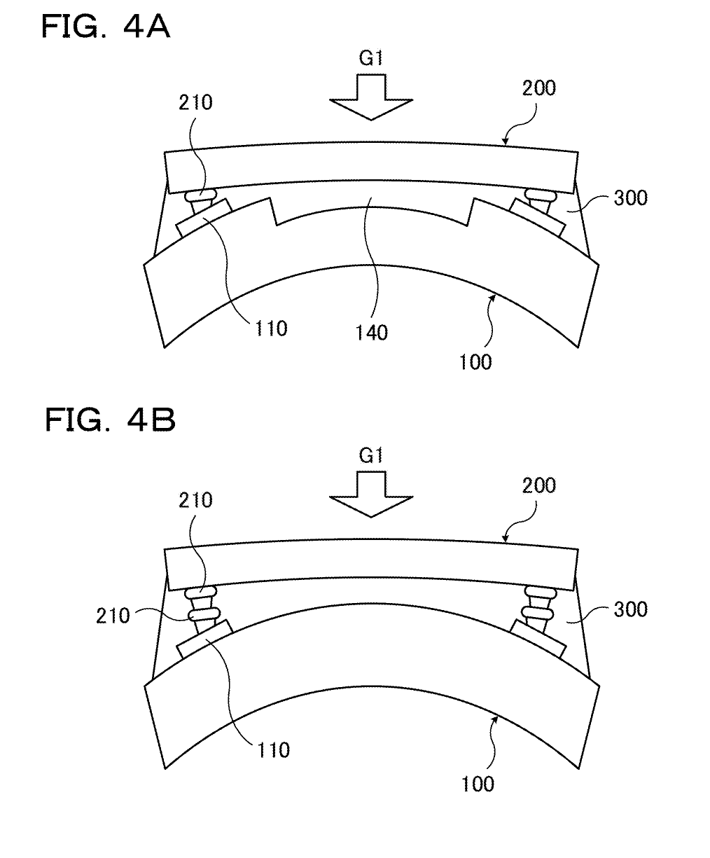

Incidentally, methods adopting constitutions as illustrated in the following FIGS. 4A and 4B are conceivable as methods for avoiding the contact between the substrate 100 and the semiconductor chip 200 or the collision of the filler contained in the adhesive 300 with the semiconductor chip 200.

FIGS. 4A and 4B are diagrams of assistance in explaining other examples of a pressure contact method. FIG. 4A and FIG. 4B are each a fragmentary sectional schematic view of a process of joining the substrate and the semiconductor chip to each other.

As illustrated in FIG. 4A, for example, a recessed portion 140 is provided in a region of the substrate 100, the region being below the semiconductor chip 200. A gap is secured between the substrate 100 and the semiconductor chip 200 by providing the recessed portion 140 even when a warp larger than that of the semiconductor chip 200 occurs in the substrate 100. It is thereby possible to avoid the contact between the substrate 100 and the semiconductor chip 200 or the collision of the filler contained in the adhesive 300 with the semiconductor chip 200. It is therefore possible also to increase the pressure contact force between the pad 110 and the bump 210 by increasing the bonding load G1. However, thus providing the recessed portion 140 invites inconveniences such as a decrease in a degree of freedom of arrangement of wiring disposed in the substrate 100 and resulting limitation of applicable product types.

In addition, as illustrated in FIG. 4B, the height of the bump 210 of the semiconductor chip 200 is increased by changing the bump 210 of the semiconductor chip 200 into a structure of a plurality of stages (structure of two stages as an example), or the film thickness of the pad 110 of the substrate 100 is increased, though not illustrated. Thus, even when a warp occurs in the substrate 100 and the semiconductor chip 200, it is possible to secure a gap between the substrate 100 and the semiconductor chip 200, and thereby avoid the contact between the substrate 100 and the semiconductor chip 200 or the collision of the filler contained in the adhesive 300 with the semiconductor chip 200. It is therefore possible also to increase the pressure contact force between the pad 110 and the bump 210 by increasing the bonding load G1. However, increasing the height of the bump 210 group or increasing the film thickness of the pad 110 invites an increase in cost of the semiconductor chip 200 and the substrate 100 and in turn an electronic device obtained by joining the semiconductor chip 200 and the substrate 100 to each other.

Thus adopting the constitution as illustrated in FIG. 4A or FIG. 4B may avoid the contact between the substrate 100 and the semiconductor chip 200, and increase the pressure contact force between the pad 110 and the bump 210 by increasing the bonding load G1. On the other hand, however, a decrease in degree of freedom of arrangement of wiring, limitation of product types, and an increase in cost are incurred.

In addition, when it is difficult to increase the bonding load G1 in the first place, as described with reference to the foregoing FIG. 3, it is difficult to enhance coupling quality and coupling reliability by making a sufficient pressure contact force act on the pad 110 of the substrate 100 and the bump 210 of the semiconductor chip 200.

With increases in the number of pins of the semiconductor chip 200 due to enhancement of performance or enhancement of functionality, it is considered to be increasingly important to enhance coupling quality and coupling reliability by making a sufficient pressure contact force act on respective contact portions of a large number of bumps 210 and pads 110, and consequently suppressing an increase in resistance or a failure in coupling.

The above description takes, as an example, coupling between the pad 110 of the substrate 100 and the bump 210 of the semiconductor chip 200 by the pressure contact method. However, without being limited to this, problems similar to the above-described problems may occur in coupling between terminals of various kinds of electronic parts by the pressure contact method.

In view of the above points, in the following, an increase in pressure contact force (load) acting between terminals of electronic parts is achieved by adopting constitutions as illustrated as embodiments in the following.

A first embodiment will first be described.

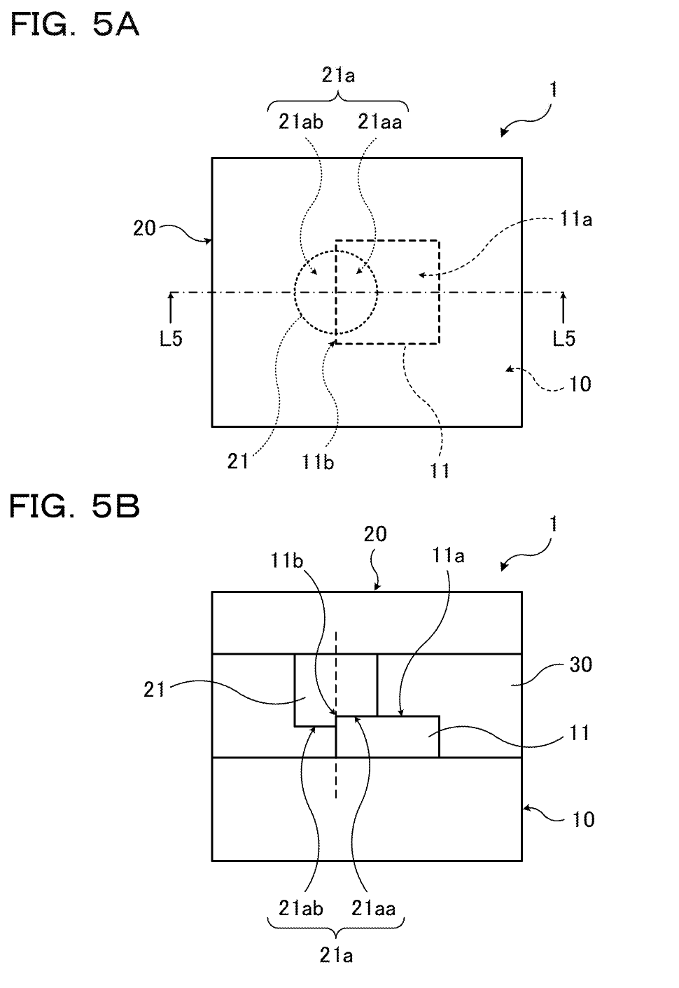

FIGS. 5A and 5B are diagrams illustrating an example of an electronic device according to a first embodiment. FIG. 5A is a fragmentary plan schematic view of the electronic device according to the first embodiment. FIG. 5B is a sectional schematic view taken along a line L5-L5 of FIG. 5A.

An electronic device 1 illustrated in FIG. 5A and FIG. 5B includes an electronic part 10, an electronic part 20 disposed over the electronic part 10, and an adhesive 30 disposed between the electronic part 10 and the electronic part 20.

The electronic part 10 is various kinds of substrates such as a package substrate, a main substrate, and an interposer. In this case, each substrate may be a rigid board, or may be a flexible board. The electronic part 10 may also be various kinds of semiconductor devices such as a semiconductor chip and a semiconductor package including a semiconductor chip.

The electronic part 10 includes a terminal 11 on a surface opposed to the electronic part 20. The terminal 11 is coupled to wiring (not illustrated) provided in the electronic part 10. The terminal 11 is a conductor layer such as a pad or a land, which is coupled to the wiring of the electronic part 10 or provided as a part of the wiring of the electronic part 10. Here, the terminal 11 of a rectangular shape in plan is illustrated as an example. Various kinds of conductor materials such as Cu and Au are used as the terminal 11. The electronic part 10 may include a plurality of such terminals 11. However, one terminal 11 is illustrated here.

The electronic part 20 is various kinds of semiconductor devices such as a semiconductor chip and a semiconductor package including a semiconductor chip. The electronic part 20 may also be various kinds of substrates such as a package substrate, a main substrate, an interposer, and the like.

The electronic part 20 includes a terminal 21 on a surface opposed to the electronic part 10, the terminal 21 being disposed to correspond to the terminal 11 of the electronic part 10. The terminal 21 is coupled to wiring (not illustrated) provided in the electronic part 20. The terminal 21 is a projecting electrode such as a bump or a pillar coupled to the wiring of the electronic part 20. Here, the terminal 21 of a circular shape in plan is illustrated as an example. Various kinds of conductor materials such as Au and Cu are used as the terminal 21. The electronic part 20 may include a plurality of such terminals 21. However, one terminal 21 is illustrated here.

The terminal 21 of the electronic part 20 is brought into contact with the terminal 11 of the electronic part 10. For example, the terminal 21 of the electronic part 20 is brought into contact and pressure contact with the terminal 11 of the electronic part 10 by pressurizing the electronic part 20 with a given bonding load by the pressure contact method as described later.

Here, as illustrated in FIG. 5A and FIG. 5B, an end 21a of the terminal 21 of the electronic part 20 includes an end part 21aa in contact with an upper surface 11a of the terminal 11 of the electronic part 10 and an end part 21ab located on the outside of the terminal 11 of the electronic part 10. One end part 21aa overlaps the terminal 11 of the electronic part 10 as viewed in plan. The other end part 21ab is located on the outside of the terminal 11 of the electronic part 10 as viewed in plan.

Incidentally, FIG. 5B illustrates, as an example, a case where the end part 21ab located on the outside of the terminal 11 is located at a position lower than the end part 21aa in contact with the upper surface 11a of the terminal 11, for example, located on a side surface of the terminal 11 of the electronic part 10. A structure as illustrated in FIG. 5B may be obtained depending on a degree of pressurization in the pressure contact method as described later and a combination of materials (hardness) of the terminal 11 of the electronic part 10 and the terminal 21 of the electronic part 20. Without being limited to such a structure, depending on the degree of pressurization and the combination of the materials, a structure may also be obtained in which the end part 21aa and the end part 21ab of the terminal 21 of the electronic part 20 are located in a same plane.

As illustrated in FIG. 5A and FIG. 5B, the terminal 21 of the electronic part 20 is disposed to be displaced from the terminal 11 of the electronic part 10, and not all of the end 21a is in contact with the upper surface 11a of the terminal 11, but the end part 21aa, which is a part of the end 21a, is in contact with the upper surface 11a of the terminal 11. The end 21a of the terminal 21 is in contact with an edge 11b of the terminal 11.

As an example, the terminal 21 of the electronic part 20 is disposed to be displaced outward from the edge 11b of the terminal 11 of the electronic part 10 by an amount equal to or more than half of the planar size (diameter) of the end 21a. In this case, the area of the end part 21ab in the end 21a, the end part 21ab being located on the outside of the terminal 11, is substantially equal to or larger than the area of the end part 21aa in contact with the upper surface 11a of the terminal 11. Here, as an example, a case is illustrated in which the terminal 21 is disposed to be displaced outward from the edge 11b of the terminal 11 by an amount corresponding to half of the end 21a, and the area of the end part 21ab is substantially equal to the area of the end part 21aa.

The electronic part 10 and the electronic part 20 having the terminal 11 and the terminal 21 (the end part 21aa of the terminal 21) in contact with each other are bonded to each other by the adhesive 30 interposed between the electronic part 10 and the electronic part 20. A thermosetting resin cured by heating or a thermosetting resin containing an inorganic or organic insulative filler, for example, is used as the adhesive 30. Not only a thermosetting resin but also a photocuring resin, which is cured by being irradiated with light such as ultraviolet light may be used as the adhesive 30. The adhesive 30 is cured in a state in which the terminal 11 and the terminal 21 are in contact with each other. The cured adhesive 30 bonds and fixes the electronic part 10 and the electronic part 20 to each other. Further, contact between the terminal 11 and the terminal 21 is maintained by the bonding of the electronic part 10 and the electronic part 20 to each other by the cured adhesive 30.

Description will next be made of an example of a method of forming the electronic device 1 as described above.

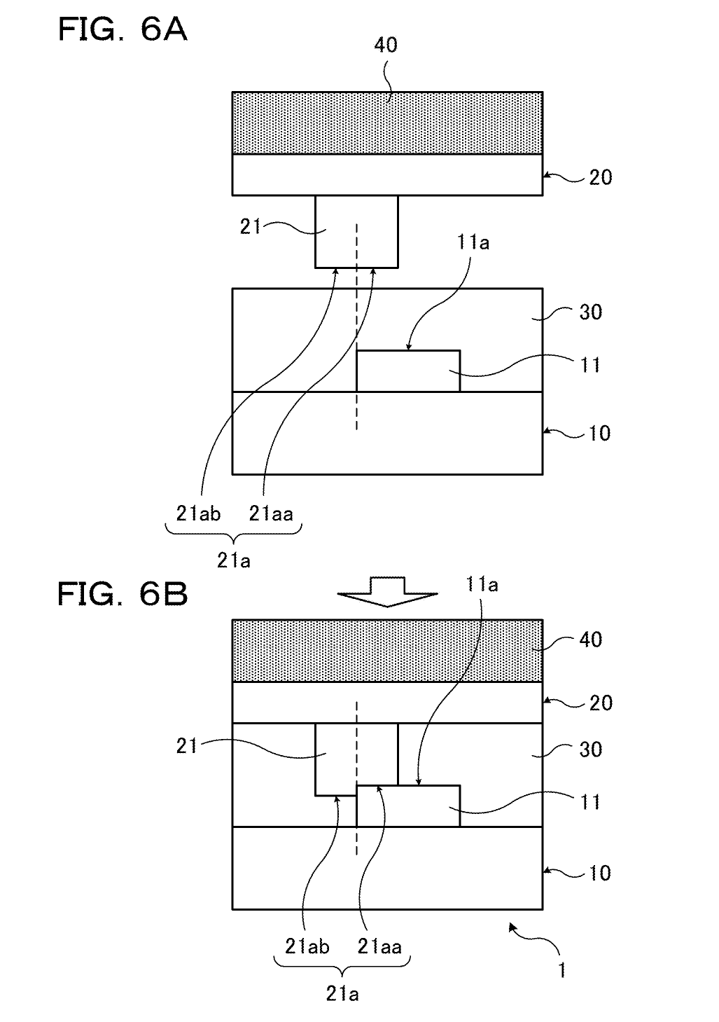

FIGS. 6A and 6B are diagrams illustrating an example of a method of forming an electronic device according to the first embodiment. FIG. 6A is a fragmentary sectional schematic view of a process of arranging electronic parts. FIG. 6B is a fragmentary sectional schematic view of a process of joining the electronic parts to each other.

The electronic device 1 is, for example, formed by mounting the electronic part 20 on the electronic part 10 by the pressure contact method.

First, as illustrated in FIG. 6A, the electronic part 10 provided with the terminal 11 and the electronic part 20 provided with the terminal 21 are prepared. The adhesive 30 is provided on a surface of the prepared electronic part 10, the surface being on a side where the terminal 11 is disposed. Then, a bonding tool 40 is used, and the electronic part 20 is disposed to be opposed to the electronic part 10 above the electronic part 10 provided with the adhesive 30, with the terminal 21 of the electronic part 20 aligned with the terminal 11 of the electronic part 10. At this time, the terminal 21 of the electronic part 20 is aligned such that the end part 21aa, which is a part of the end 21a of the terminal 21 of the electronic part 20, is located above the terminal 11, and such that the end part 21ab, which is the other part of the end 21a of the terminal 21 of the electronic part 20, is located outwardly above the terminal 11.

Next, as illustrated in FIG. 6B, the electronic part 20 is pressurized and heated by the bonding tool 40, and thus the terminal 21 of the electronic part 20 is brought into pressure contact with the terminal 11 of the electronic part 10. The end part 21aa in the end 21a of the terminal 21 of the electronic part 20 is brought into contact (collision), for example, pressure contact with the upper surface 11a of the terminal 11 by the pressurization. The end part 21ab in the end 21a of the terminal 21 is located on the outside of the terminal 11. In a case where a thermosetting resin is used as the adhesive 30, the adhesive 30 is cured by heating in a state in which the terminal 21 is thus in pressure contact with the terminal 11. In a case where a photocuring resin is used as the adhesive 30, the adhesive 30 is cured by irradiating the adhesive 30 with light in the state in which the terminal 21 is in pressure contact with the terminal 11.

A compressive force accompanying curing shrinkage occurs in the adhesive 30. The terminal 11 and the terminal 21 are brought into pressure contact with each other by a bonding load at the time of pressurizing the terminal 21 to the terminal 11 side, a reaction force occurring from the terminal 11 side to the terminal 21 side in response to the pressurization, and the compressive force accompanying the curing shrinkage of the adhesive 30. The adhesive 30 bonds the electronic part 20 and the electronic part 10 to each other, and maintains or reinforces the pressure contact between the terminal 11 and the terminal 21. The electronic part 10 and the electronic part 20 are thus mechanically and electrically joined to each other.

The electronic device 1 is obtained by such a pressure contact method.

Incidentally, in the electronic device 1, contact between the terminal 11 and the terminal 21 is maintained by bonding the electronic part 10 and the electronic part 20 to each other by the adhesive 30. When the electronic part 10 and the electronic part 20 are not bonded to each other by the adhesive 30, practical contact (mechanical and electric joining) between the terminal 11 and the terminal 21 is not maintained. In such a respect, the state of the contact between the terminal 11 and the terminal 21, which state is obtained by the pressure contact method, is different from a state of a junction portion between terminals in which portion practical mechanical and electric joining is achieved by metallic diffusion or reaction (alloying), the state of the junction portion being obtained by another method such as a solder joint method or an ultrasonic joining method.

As described above, in the electronic device 1, the end part 21aa as a part of the end 21a of the terminal 21 of the electronic part 20 is brought into contact, for example, pressure contact with the upper surface 11a of the terminal 11 of the electronic part 10. When a part of the end 21a of the terminal 21 is thus brought into pressure contact with the upper surface 11a of the terminal 11, a force (load) applied to contact portions of the terminal 21 and the terminal 11 is increased as compared with a case where the whole of the end 21a of the terminal 21 is in pressure contact with the upper surface 11a of the terminal 11. For example, when a part of the end 21a of the terminal 21 is brought into pressure contact with the upper surface 11a of the terminal 11, a load per unit area at the contact portions of the terminal 21 and the terminal 11 is increased even with a same bonding load as in the case where the whole of the end 21a of the terminal 21 is brought into pressure contact with the upper surface 11a of the terminal 11. In addition, a compressive force per unit area at the contact portions of the terminal 21 and the terminal 11, the compressive force resulting from the curing shrinkage of the adhesive 30, is also increased. As a result, stress occurring in the contact portions of the terminal 21 and the terminal 11 is increased, and the pressure contact between the terminal 21 and the terminal 11 is maintained or reinforced by the adhesive 30. Because a high pressure contact force is obtained between the terminal 21 and the terminal 11, an increase in resistance or a failure in coupling between the terminal 21 and the terminal 11 is suppressed, and consequently coupling quality and coupling reliability are enhanced.

Thus, in the electronic device 1, the pressure contact force between the terminal 21 and the terminal 11 is enhanced by bringing a part of the terminal 21 into pressure contact with the terminal 11. Therefore, the bonding load at the time of the pressurization does not necessarily need to be increased to obtain a given pressure contact force. It is consequently possible to avoid contact between the electronic part 10 and the electronic part 20 and resulting damage thereto, the contact and the resulting damage being caused by increasing the bonding load at the time of pressurizing the electronic part 20 in a case where a warp occurs in the electronic part 10, for example. Incidentally, it is also unnecessary for the electronic part 10 or the electronic part 20 to adopt a recessed portion or a terminal structure of a plurality of stages for a purpose of widening a gap between the electronic part 10 and the electronic part 20 in order to avoid such contact between the electronic part 10 and the electronic part 20. In addition, it is not necessarily necessary to change to such an adhesive 30 as to provide a larger compressive force by curing shrinkage to obtain a given pressure contact force.

In the electronic device 1, a part of the terminal 21 is brought into pressure contact with the terminal 11. It is thus possible to realize a high pressure contact force between the terminal 21 and the terminal 11 while adhering to process conditions (the bonding load and the kind of the adhesive 30) without changing the specifications of the terminal 21 and the terminal 11.

A second embodiment will next be described.

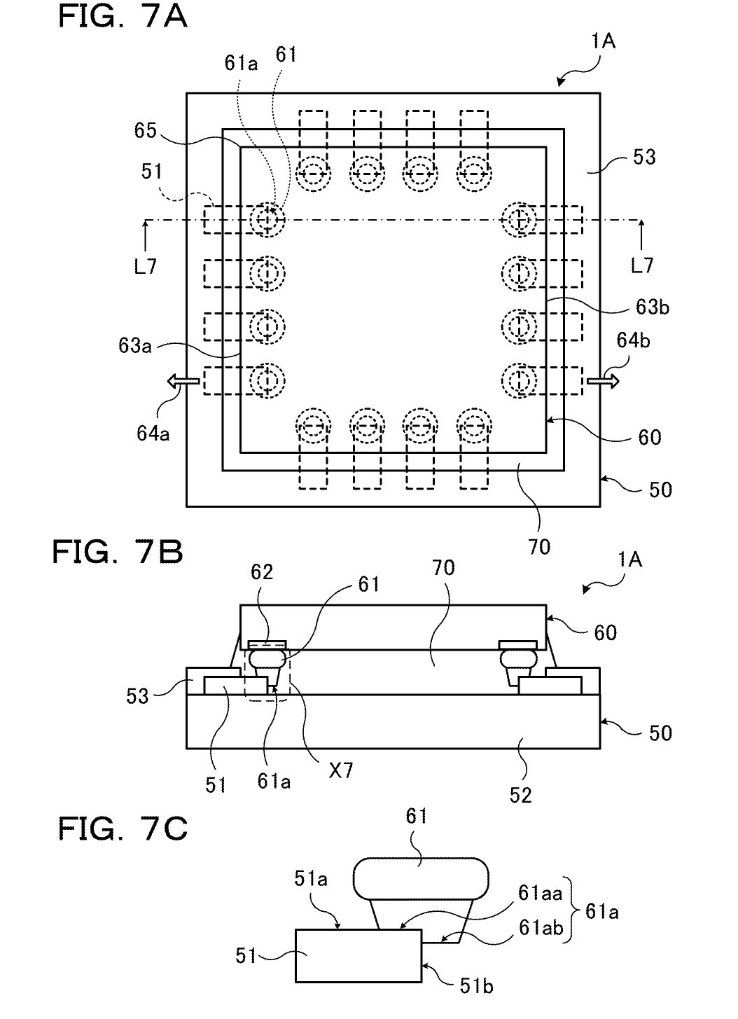

FIGS. 7A, 7B, and 7C are diagrams illustrating an example of an electronic device according to a second embodiment. FIG. 7A is a fragmentary plan schematic view of the electronic device according to the second embodiment. FIG. 7B is a sectional schematic view taken along a line L7-L7 of FIG. 7A. FIG. 7C is an enlarged schematic view of an X7 portion in FIG. 7B.

An electronic device 1A illustrated in FIG. 7A and FIG. 7B (and FIG. 7C) includes a substrate 50, a semiconductor chip 60 disposed over the substrate 50, and an adhesive 70 disposed between the substrate 50 and the semiconductor chip 60.

The substrate 50 includes a base material 52 as well as a plurality of pads 51 (terminals) and a protective film 53 that are disposed on a surface of the base material 52, the surface being opposed to the semiconductor chip 60. The base material 52, for example, includes a base material such as a core resin substrate and a base material such as prepreg disposed thereon. Cu, for example, is used as the pads 51. For example, used as the pads 51 are Cu pads or pads having a structure formed by laminating a nickel (Ni) layer and an Au layer to the surfaces of Cu pads (Cu/Ni/Au pads). A solder resist, for example, is used as the protective film 53. The pads 51 are coupled to wiring (not illustrated) disposed in the substrate 50, and are each arranged to correspond to a plurality of bumps 61 provided in a peripheral arrangement to the semiconductor chip 60, as will be described later. Each of the pads 51 is covered by the protective film 53 such that an upper surface 51a and a part of an edge 51b of the pad 51 are exposed.

The semiconductor chip 60 includes a circuit element such as a transistor and a conductor portion such as wiring coupled to the circuit element, the circuit element and the conductor portion being not illustrated. A plurality of electrodes 62 coupled to such a conductor portion are arranged on a surface of the semiconductor chip 60, the surface being opposed to the substrate 50. The semiconductor chip 60 includes bumps 61 (terminals) each disposed on the plurality of electrodes 62. Cu, Al, or the like is used as the electrodes 62. Au, for example, is used as the bumps 61. For example, Au stud bumps are used as the bumps 61. Here, such Au stud bumps are illustrated. The bumps 61 are in a peripheral arrangement in which the bumps 61 are arranged along the periphery of the semiconductor chip 60.

Incidentally, while FIG. 7A and FIG. 7B illustrate the bumps 61 arranged in one row in a region along each side of the semiconductor chip 60, the bumps 61 may be arranged in a plurality of rows in the region along each side of the semiconductor chip 60. In this case, the substrate 50 is provided with a plurality of rows of pads 51 to correspond to the bumps 61 arranged in the plurality of rows for each side of the semiconductor chip 60.

As illustrated in FIGS. 7A to 7C, the bumps 61 of the semiconductor chip 60 are brought into contact with the pads 51 of the substrate 50. The bumps 61 are brought into contact, for example, pressure contact with the pads 51 of the substrate 50 by pressurizing the semiconductor chip 60 with a given bonding load by the pressure contact method as described later.

Here, an end 61a of each of the bumps 61 of the semiconductor chip 60 includes an end part 61aa in contact with the upper surface 51a of the corresponding pad 51 of the substrate 50 and an end part 61ab located on the outside of the pad 51 of the substrate 50. One end part 61aa overlaps the pad 51 of the substrate 50 as viewed in plan. The other end part 61ab is located on the outside of the pad 51 of the substrate 50 as viewed in plan. Incidentally, FIG. 7B and FIG. 7C illustrate, as an example, a case where the end part 61ab located on the outside of the pad 51 is located at a position lower than the end part 61aa in contact with the upper surface 51a of the pad 51, for example, located on a side surface of the pad 51 of the substrate 50.

In the electronic device 1A, the bump 61 of the semiconductor chip 60 is disposed to be displaced from the pad 51 of the substrate 50, and the end part 61aa as a part of the end 61a of the bump 61 of the semiconductor chip 60 is in contact with the upper surface 51a of the pad 51. The bump 61 is disposed to be displaced outward from the edge 51b of the pad 51 by an amount equal to or more than half of the planar size (diameter) of the end 61a of the bump 61.

In the electronic device 1A, the pads 51 of the substrate 50, the pads 51 corresponding to the bumps 61 arranged in a region along one side of the semiconductor chip 60, are disposed to be displaced relative to the bumps 61 in a direction orthogonal to the one side. Here, as an example, the electronic device 1A is illustrated in which, with respect to the bumps 61 arranged in a region along one side of the semiconductor chip 60, the corresponding pads 51 of the substrate 50 on which the semiconductor chip 60 is mounted are arranged to be displaced in an outward direction (sideward) of the semiconductor chip 60, the outward direction being orthogonal to the one side.

In the electronic device 1A, displacements (for example, a displacement 64a and a displacement 64b) of the pads 51 with respect to the bumps 61 in respective regions along one side and an opposite side (for example, a side 63a and a side 63b) of the semiconductor chip 60, the opposite side being opposed to the one side, are opposite to each other. For example, in contact portions in the respective regions along the one side and the opposite side, directions of going from the end part 61aa to the end part 61ab are opposite to each other.

Such an arrangement of the electronic device 1A is, for example, realized by forming, in advance, the pads 51 of the substrate 50 on which the semiconductor chip 60 is to be mounted, the pads 51 corresponding to the bumps 61, such that the corresponding pads 51 are displaced in the outward direction of the semiconductor chip 60 with respect to the bumps 61 of the semiconductor chip 60. Alternatively, such an arrangement of the electronic device 1A is realized by forming, in advance, the bumps 61 of the semiconductor chip 60 such that the bumps 61 are displaced in an inward direction of the semiconductor chip 60 with respect to the corresponding pads 51 of the substrate 50 on which the semiconductor chip 60 is to be mounted.

The substrate 50 and the semiconductor chip 60 having the pads 51 and the bumps 61 in contact with each other are bonded to each other by the adhesive 70 interposed between the substrate 50 and the semiconductor chip 60. A thermosetting resin, for example, is used as the adhesive 70. A cured adhesive 70 bonds and fixes the substrate 50 and the semiconductor chip 60 to each other, and maintains the contact between the pads 51 and the bumps 61.

The electronic device 1A as described above is, for example, formed by the pressure contact method.

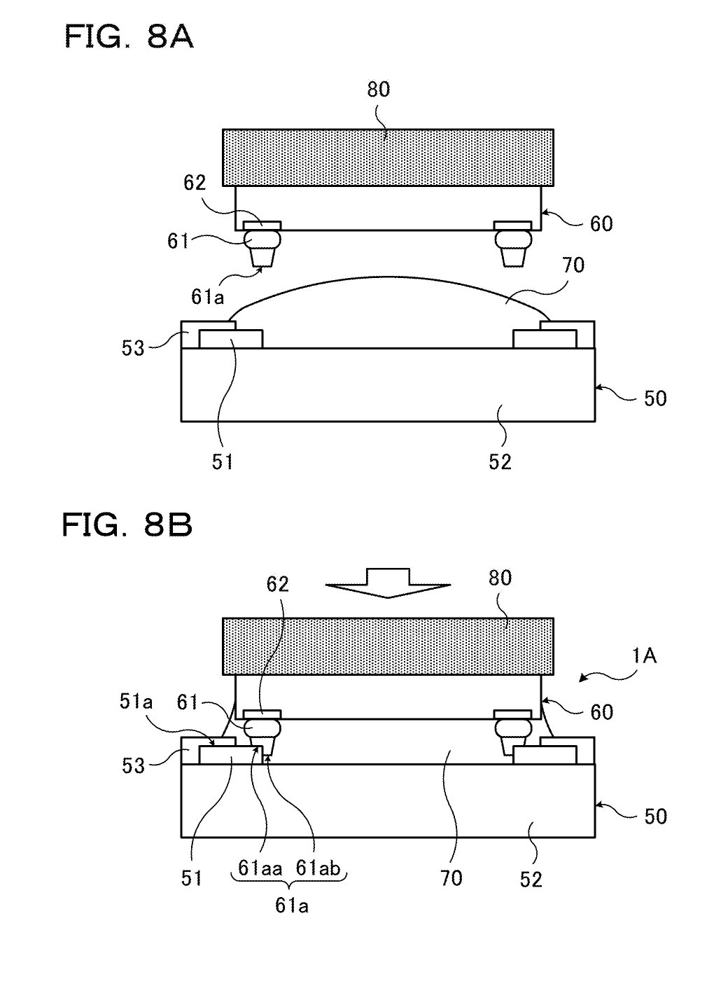

FIGS. 8A and 8B are diagrams illustrating an example of a method of forming an electronic device according to the second embodiment. FIG. 8A is a fragmentary sectional schematic view of a process of arranging the substrate and the semiconductor chip. FIG. 8B is a fragmentary sectional schematic view of a process of joining the substrate and the semiconductor chip to each other.

First, as illustrated in FIG. 8A, the substrate 50 provided with the pads 51 and the semiconductor chip 60 provided with the bumps 61 are prepared. The adhesive 70 is provided on a surface of the prepared substrate 50, the surface being on a side where the pads 51 are arranged. Then, a bonding tool 80 is used, and the semiconductor chip 60 is disposed to be opposed to the substrate 50 above the substrate 50 provided with the adhesive 70, with the bumps 61 of the semiconductor chip 60 aligned with the pads 51 of the substrate 50. At this time, the bumps 61 of the semiconductor chip 60 are each aligned such that a part of the end 61a is located above the pad 51, and such that the other part of the end 61a is located outwardly above the pad 51.

Next, as illustrated in FIG. 8B, the semiconductor chip 60 is pressurized and heated by the bonding tool 80, and thus the bumps 61 of the semiconductor chip 60 are brought into pressure contact with the pads 51 of the substrate 50. The end part 61aa as a part of the end 61a of each of the bumps 61 of the semiconductor chip 60 is brought into contact (collision), for example, pressure contact with the upper surface 51a of the pad 51 by the pressurization. The end part 61ab as the other part of the end 61a of the bump 61 is located on the outside of the pad 51. The adhesive 70 is cured by heating in a state in which the bumps 61 are thus in pressure contact with the pads 51.

The displacements of the pads 51 of the substrate 50 with respect to the bumps 61 at the opposed sides of the semiconductor chip 60 are opposite to each other. Thus, at a time of mounting by the pressure contact method, movement of the semiconductor chip 60 in a planar direction is regulated, and therefore positional displacement of the semiconductor chip 60 in the planar direction is suppressed.

The pads 51 are brought into pressure contact with the bumps 61 by a bonding load at the time of pressurizing the bumps 61 to the side of the pads 51, a reaction force occurring from the pads 51 to the side of the bumps 61 in response to the pressurization, and a compressive force accompanying the curing shrinkage of the adhesive 70. The adhesive 70 bonds the semiconductor chip 60 and the substrate 50 to each other, and maintains or reinforces the pressure contact between the pads 51 and the bumps 61. The substrate 50 and the semiconductor chip 60 are thus mechanically and electrically joined to each other.

In the electronic device 1A, the end part 61aa as a part of the end 61a of each of the bumps 61 of the semiconductor chip 60 is brought into contact, for example, pressure contact with the upper surface 51a of the pad 51 of the substrate 50. A load applied to contact portions of the bump 61 and the pad 51 or stress occurring in the contact portions is thereby increased as compared with a case where the whole of the end 61a of the bump 61 is in pressure contact with the upper surface 51a of the pad 51.

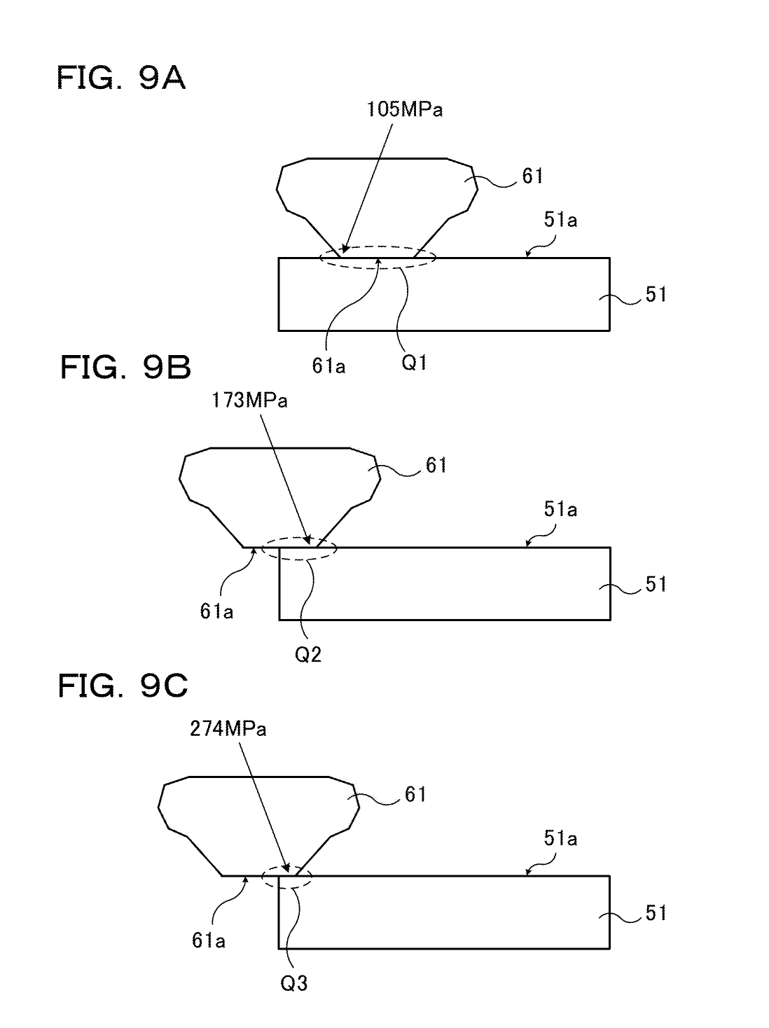

Here, FIGS. 9A, 9B, and 9C are diagrams of assistance in explaining a result of analysis of stress in an electronic device according to the second embodiment.

FIG. 9A illustrates, for comparison, a schematic diagram of a stress analysis model and a maximum stress value in a case where the whole of the end 61a of the bump 61 is in pressure contact with the upper surface 51a of the pad 51. FIG. 9B illustrates a schematic diagram of a stress analysis model and a maximum stress value in a case where a part of the end 61a of the bump 61 is brought into pressure contact with the upper surface 51a of the pad 51, the part corresponding to 50% of the diameter of the end 61a from the outer circumference as viewed in a section passing through the center of the plane of the end 61a. FIG. 9C illustrates a schematic diagram of a stress analysis model and a maximum stress value in a case where a part of the end 61a of the bump 61 is brought into pressure contact with the upper surface 51a of the pad 51, the part corresponding to 25% of the diameter of the end 61a from the outer circumference as viewed in the section passing through the center of the plane of the end 61a. For stress analysis, simulation is performed supposing that the bump 61 is an Au stud bump, that the pad 51 is a Cu/Ni/Au pad, and that the bonding load is 15 g/bump.

As illustrated in FIG. 9A, a maximum value of stress occurring in contact portions Q1 of the bump 61 and the pad 51 is 105 MPa in the case where the whole of the end 61a of the bump 61 is brought into pressure contact with the upper surface 51a of the pad 51. On the other hand, as illustrated in FIG. 9B, a maximum value of stress occurring in contact portions Q2 of the bump 61 and the pad 51 is 173 MPa in the case where a part of the end 61a of the bump 61 is brought into pressure contact with the upper surface 51a of the pad 51, the part corresponding to 50% of the diameter of the end 61a from the outer circumference as viewed in the section passing through the center of the plane of the end 61a. In addition, as illustrated in FIG. 9C, a maximum value of stress occurring in contact portions Q3 of the bump 61 and the pad 51 is 274 MPa in the case where a part of the end 61a of the bump 61 is brought into pressure contact with the upper surface 51a of the pad 51, the part corresponding to 25% of the diameter of the end 61a from the outer circumference as viewed in the section passing through the center of the plane of the end 61a.

As in the contact portions Q1 to Q3 in FIGS. 9A to 9C, when the area of the contact portions of the bump 61 and the pad 51 is decreased, a load per unit area of the contact portions of the bump 61 and the pad 51 is increased for a fixed bonding load at the time of pressurizing the semiconductor chip 60 by the pressure contact method. As the load per unit area of the contact portions of the bump 61 and the pad 51 is increased, stress occurring in the contact portions of the bump 61 and the pad 51 is increased.

Thus, in the electronic device 1A, a part of the end 61a of the bump 61 is brought into pressure contact with the upper surface 51a of the pad 51. The stress occurring in the contact portions of the bump 61 and the pad 51 is thereby increased. For example, it may be said that a pressure contact force acting on the contact portions of the bump 61 and the pad 51 is increased. According to the method of thus bringing a part of the bump 61 into pressure contact with the pad 51, it is possible to enhance the pressure contact force between the bump 61 and the pad 51 while adhering to process conditions (the bonding load and the kind of the adhesive 70) without changing the specifications of the bump 61 and the pad 51. The pressure contact force between the bump 61 and the pad 51 is enhanced, and therefore an increase in resistance or a failure in coupling between the bump 61 and the pad 51 is suppressed. The electronic device 1A excellent in coupling quality and coupling reliability is realized.

Incidentally, while an Au stud bump is illustrated as the bump 61 here, stud bumps of other metallic materials (Cu and the like) may be used. In addition, there is no limitation to stud bumps. Pillar electrodes, ball-shaped electrodes, and the like formed by using various kinds of metallic materials may be used.

In addition, the substrate 50 may be various kinds of substrates such as a printed board used as a package substrate or a main substrate and an interposer having a semiconductor (silicon or the like) or glass as a base material. The electronic part mounted on the substrate 50 may be not only the semiconductor chip 60 but also various kinds of semiconductor devices such as a semiconductor package formed by mounting a semiconductor chip on a package substrate.

A third embodiment will next be described.

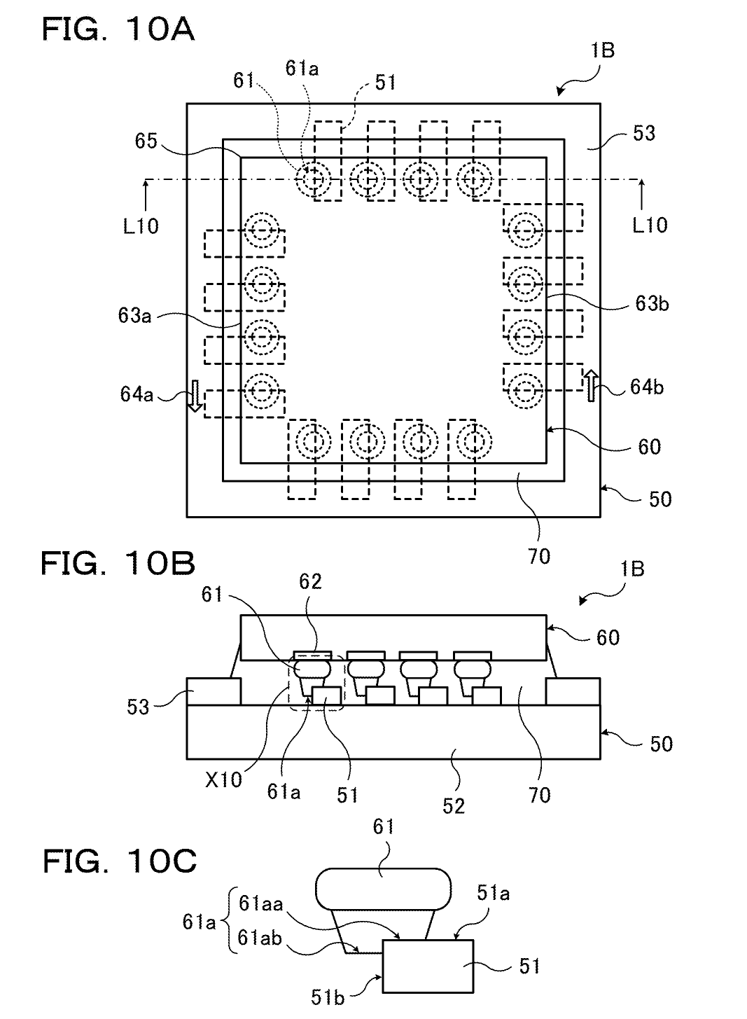

FIGS. 10A, 10B, and 10C are diagrams illustrating an example of an electronic device according to a third embodiment. FIG. 10A is a fragmentary plan schematic view of the electronic device according to the third embodiment. FIG. 10B is a sectional schematic view taken along a line L10-L10 of FIG. 10A. FIG. 10C is an enlarged schematic view of an X10 portion in FIG. 10B.

In the electronic device 1B illustrated in FIG. 10A and FIG. 10B (and FIG. 10C), a bump 61 group and a pad 51 group arranged in a region along one side of a semiconductor chip 60 are disposed to be relatively displaced from each other in a length direction of the one side. Here, as an example, the electronic device 1B is illustrated in which the pad 51 group of a substrate 50 on which the semiconductor chip 60 is mounted, the pad 51 group corresponding to the bump 61 group in the region along the one side of the semiconductor chip 60, is disposed to be displaced from the bump 61 group in the length direction of the one side.

In the electronic device 1B, displacements (for example, a displacement 64a and a displacement 64b) of pad 51 groups with respect to bump 61 groups in respective regions along the one side and an opposite side (for example, a side 63a and a side 63b) of the semiconductor chip 60, the opposite side being opposed to the one side, are opposite to each other. An end part 61aa as a part of an end 61a of each bump 61 is in contact with an upper surface 51a of a pad 51. An end part 61ab as another part of the end 61a is located on the outside of the pad 51. In contact portion groups of the bumps 61 and the pads 51 in the respective regions along the one side and the opposite side, directions of going from the end part 61aa to the end part 61ab are opposite to each other.

Such an arrangement of the electronic device 1B is, for example, realized by forming, in advance, the pad 51 group of the substrate 50 on which the semiconductor chip 60 is to be mounted, the pad 51 group corresponding to the bump 61 group, such that the corresponding pad 51 group is displaced in the length direction of the one side with respect to the bump 61 group in the region along the one side of the semiconductor chip 60. Alternatively, such an arrangement of the electronic device 1B is realized by forming, in advance, the bump 61 group in the region along the one side of the semiconductor chip 60 such that the bump 61 group is displaced in the length direction of the one side with respect to the corresponding pad 51 group of the substrate 50 on which the semiconductor chip 60 is to be mounted.

As with the electronic device 1A described in the foregoing second embodiment, the electronic device 1B as described above is, for example, formed by the pressure contact method. For example, the semiconductor chip 60 is disposed to be opposed to the substrate 50 above the substrate 50 provided with the adhesive 70, with the bumps 61 of the semiconductor chip 60 aligned with the pads 51 of the substrate 50. Pressurization and heating are thereafter performed, and the adhesive 70 is cured. The displacements of the pad 51 groups of the substrate 50 with respect to the bump 61 groups at the opposed sides of the semiconductor chip 60 are opposite to each other. Thus, at a time of mounting by the pressure contact method, movement of the semiconductor chip 60 in a planar direction is regulated, and therefore positional displacement of the semiconductor chip 60 in the planar direction is suppressed.

As illustrated in FIGS. 10A to 10C, in the electronic device 1B, the end part 61aa as a part of the end 61a of each of the bumps 61 of the semiconductor chip 60 is brought into contact, for example, pressure contact with the upper surface 51a of the pad 51 of the substrate 50. Thus, a load applied to contact portions of the bump 61 and the pad 51 or stress occurring in the contact portions is increased, so that a pressure contact force is enhanced. The electronic device 1B excellent in coupling quality and coupling reliability is realized in which the pressure contact force between the bump 61 and the pad 51 is enhanced, and therefore an increase in resistance or a failure in coupling between the bump 61 and the pad 51 is suppressed.

A fourth embodiment will next be described.

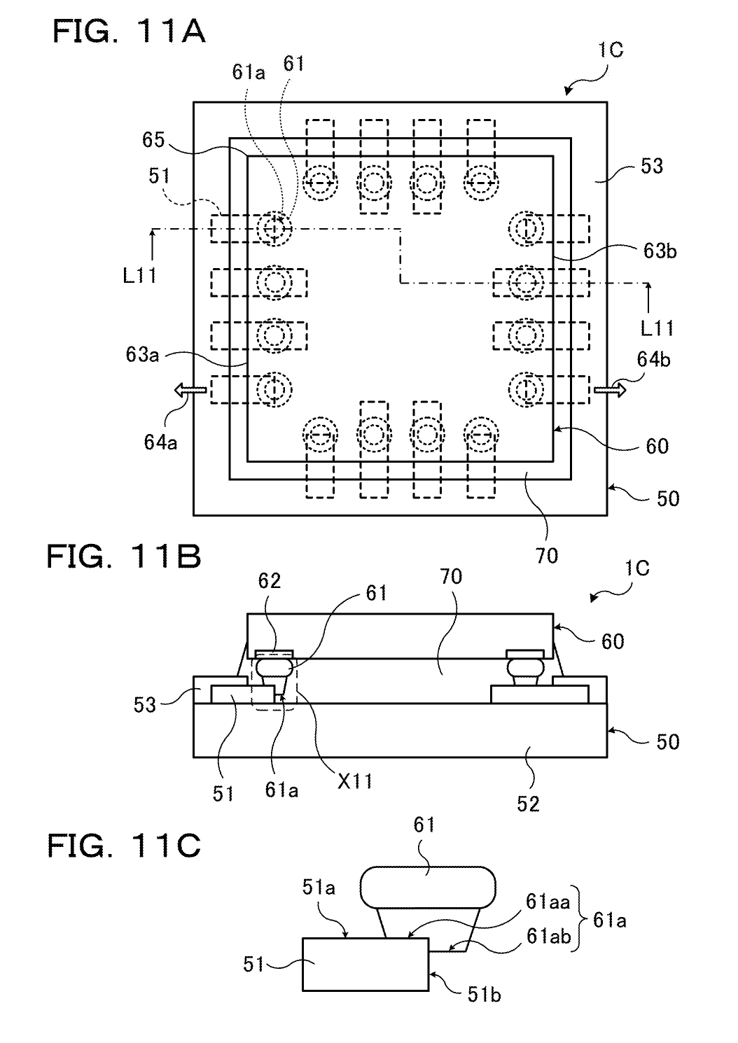

FIGS. 11A, 11B, and 11C are diagrams illustrating an example of an electronic device according to a fourth embodiment. FIG. 11A is a fragmentary plan schematic view of the electronic device according to the fourth embodiment. FIG. 11B is a sectional schematic view taken along a line L11-L11 of FIG. 11A. FIG. 11C is an enlarged schematic view of an X11 portion in FIG. 11B.

In the electronic device 1C illustrated in FIG. 11A and FIG. 11B (and FIG. 11C), a pad 51 of a substrate 50, the pad 51 corresponding to a bump 61 arranged in the vicinity of a corner portion 65 of one side of a semiconductor chip 60, is disposed to be displaced relative to the bump 61 in a direction orthogonal to the one side. The bump 61 disposed in the vicinity of the corner portion 65 of the semiconductor chip 60 is, for example, one bump 61 or two or more bumps 61 disposed in a region corresponding to 30% or less of the side length of the semiconductor chip 60 from the corner portion 65. Here, as an example, the electronic device 1C is illustrated in which the pad 51 of the substrate 50 on which the semiconductor chip 60 is mounted, the pad 51 corresponding to the bump 61, is disposed to be displaced in an outward direction (sideward) of the semiconductor chip 60, the outward direction being orthogonal to the one side, with respect to the bump 61 disposed in the vicinity of the corner portion 65 of the one side of the semiconductor chip 60.

In the electronic device 1C, displacements (for example, a displacement 64a and a displacement 64b) of pads 51 with respect to bumps 61 in the vicinities of corner portions 65 in respective regions along the one side and an opposite side (for example, a side 63a and a side 63b) of the semiconductor chip 60, the opposite side being opposed to the one side, are opposite to each other. An end part 61aa as a part of an end 61a of each of the bumps 61 in the vicinities of the respective corner portions 65 is in contact with an upper surface 51a of a pad 51. An end part 61ab as another part of the end 61a is located on the outside of the pad 51. In contact portions in the vicinities of the corner portions 65 in the respective regions along the one side and the opposite side, directions of going from the end part 61aa to the end part 61ab are opposite to each other.

Such an arrangement of the electronic device 1C is, for example, realized by forming, in advance, the pad 51 of the substrate 50 on which substrate the semiconductor chip 60 is to be mounted, the pad 51 corresponding to the bump 61, such that the corresponding pad 51 is displaced in an outward direction of the semiconductor chip 60 with respect to the bump 61 in the vicinity of the corner portion 65 of the semiconductor chip 60. Alternatively, such an arrangement of the electronic device 1C is realized by forming, in advance, the bump 61 in the vicinity of the corner portion 65 of the semiconductor chip 60 such that the bump 61 is displaced in an inward direction of the semiconductor chip 60 with respect to the corresponding pad 51 of the substrate 50 on which the semiconductor chip 60 is to be mounted.

As with the electronic device 1A described in the foregoing second embodiment, the electronic device 1C as described above is, for example, formed by the pressure contact method. For example, the semiconductor chip 60 is disposed to be opposed to the substrate 50 above the substrate 50 provided with the adhesive 70, with the bumps 61 of the semiconductor chip 60 aligned with the pads 51 of the substrate 50. Pressurization and heating are thereafter performed, and the adhesive 70 is cured. The displacements of the pads 51 of the substrate 50 with respect to the bumps 61 in the vicinities of the both end corner portions 65 of the opposed sides of the semiconductor chip 60 are opposite to each other. Thus, at a time of mounting by the pressure contact method, movement of the semiconductor chip 60 in a planar direction is regulated, and therefore positional displacement of the semiconductor chip 60 in the planar direction is suppressed.

As illustrated in FIGS. 11A to 11C, in the electronic device 1C, the end part 61aa as a part of the end 61a of the bump 61 in the vicinity of the corner portion 65 of the semiconductor chip 60 is brought into contact, for example, pressure contact with the upper surface 51a of the pad 51 of the substrate 50. Thus, a load applied to contact portions of the bump 61 and the pad 51 in the vicinity of the corner portion 65 or stress occurring in the contact portion is increased, so that a pressure contact force is enhanced.

As compared with an intermediate portion of the side of the semiconductor chip 60, a greater effect of a warp of the substrate 50 tends to be produced on the corner portion 65 of the semiconductor chip 60, and a gap between the corner portion 65 of the semiconductor chip 60 and the substrate 50 tends to be widened. Therefore, the pressure contact force between the bump 61 in the vicinity of the corner portion 65 and the corresponding pad 51 tends to be decreased as compared with a pressure contact force between another bump 61 and a corresponding pad 51, so that an increase in resistance or a failure in coupling tends to occur. From this viewpoint, as described above, a part of the end 61a of the bump 61 in the vicinity of the corner portion 65 is in pressure contact with the upper surface 51a of the pad 51, so that the pressure contact force between the bump 61 and the pad 51 is enhanced. Thus enhancing the pressure contact force in the vicinity of the corner portion 65 may suppress an increase in resistance or a failure in coupling between the bump 61 and the pad 51 in the vicinity of the corner portion 65. In addition, the pressure contact force is made uniform in the contact portion groups of the bumps 61 and the pads 51 in the vicinity of the corner portion 65 and in the other region. The electronic device 1C excellent in coupling quality and coupling reliability between the bumps 61 and the pads 51 is thereby realized.

A fifth embodiment will next be described.

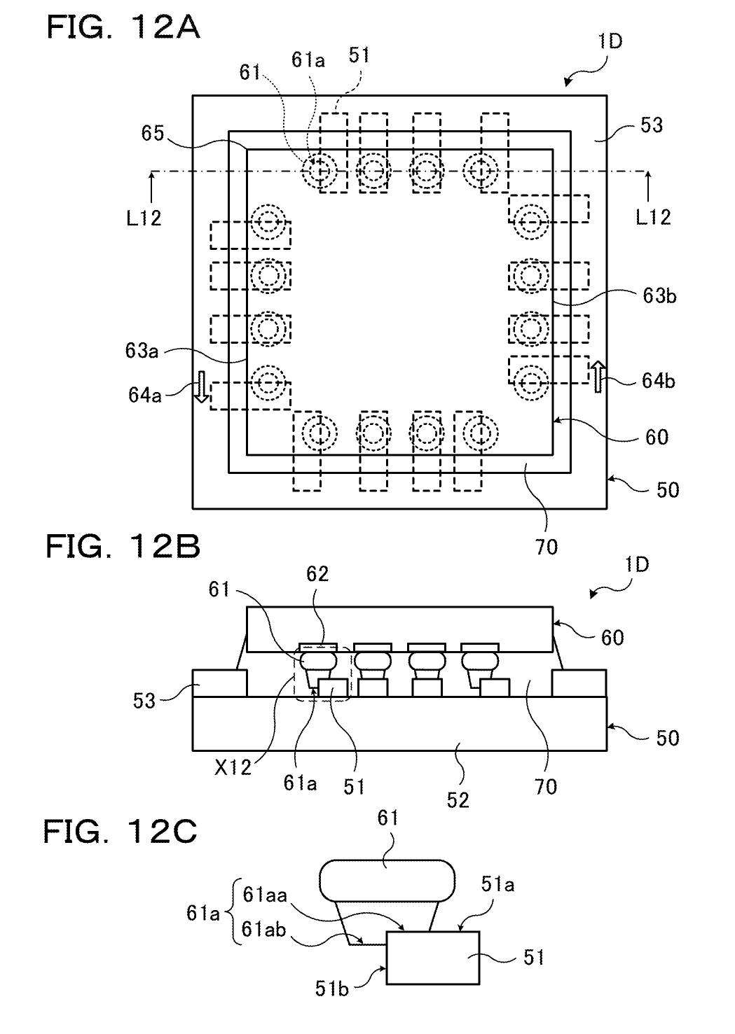

FIGS. 12A, 12B, and 12C are diagrams illustrating an example of an electronic device according to a fifth embodiment. FIG. 12A is a fragmentary plan schematic view of the electronic device according to the fifth embodiment. FIG. 12B is a sectional schematic view taken along a line L12-L12 of FIG. 12A. FIG. 12C is an enlarged schematic view of an X12 portion in FIG. 12B.

In the electronic device 1D illustrated in FIG. 12A and FIG. 12B (and FIG. 12C), pads 51 of a substrate 50, the pads 51 corresponding to bumps 61 in the vicinities of both end corner portions 65 arranged in a region along one side of a semiconductor chip 60, are disposed to be displaced relative to the bumps 61 in a length direction of the one side. Each of the bumps 61 disposed in the vicinities of the corner portions 65 of the semiconductor chip 60 is, for example, one bump 61 or two or more bumps 61 disposed in a region corresponding to 30% or less of the side length of the semiconductor chip 60 from the corner portion 65. Here, as an example, the electronic device 1D is illustrated in which the pads 51 of the substrate 50 on which the semiconductor chip 60 is mounted, the pads 51 corresponding to the bumps 61, are disposed to be displaced in the length direction of the one side with respect to the bumps 61 in the vicinities of both end corner portions 65 in the region along the one side of the semiconductor chip 60.

In the electronic device 1D, displacements (for example, a displacement 64a and a displacement 64b) of pads 51 with respect to bumps 61 in the vicinities of both end corner portions 65 in respective regions along the one side and an opposite side (for example, a side 63a and a side 63b) of the semiconductor chip 60, the opposite side being opposed to the one side, are opposite to each other. An end part 61aa as a part of an end 61a of each of the bumps 61 in the vicinity of each corner portion 65 is in contact with an upper surface 51a of a pad 51. An end part 61ab as another part of the end 61a is located on the outside of the pad 51. In contact portions in the vicinities of both end corner portions 65 in the respective regions along the one side and the opposite side, directions of going from the end part 61aa to the end part 61ab are opposite to each other.

Such an arrangement of the electronic device 1D is, for example, realized by forming, in advance, the pads 51 of the substrate 50 on which the semiconductor chip 60 is mounted, the pads 51 corresponding to the bumps 61, such that the corresponding pads 51 are displaced in the length direction of the one side with respect to the bumps 61 in the vicinities of both end corner portions 65 in the region along the one side of the semiconductor chip 60. Alternatively, such an arrangement of the electronic device 1D is realized by forming, in advance, the bumps 61 in the vicinities of both end corner portions 65 in the region along the one side of the semiconductor chip 60 such that the bumps 61 are displaced in the length direction of the one side with respect to the corresponding pads 51 of the substrate 50 on which the semiconductor chip 60 is mounted.

As with the electronic device 1A described in the foregoing second embodiment, the electronic device 1D as described above is, for example, formed by the pressure contact method. For example, the semiconductor chip 60 is disposed to be opposed to the substrate 50 above the substrate 50 provided with the adhesive 70, with the bumps 61 of the semiconductor chip 60 aligned with the pads 51 of the substrate 50. Pressurization and heating are thereafter performed, and the adhesive 70 is cured. The displacements of the pads 51 of the substrate 50 with respect to the bumps 61 in the vicinities of both end corner portions 65 at the opposed sides of the semiconductor chip 60 are opposite to each other. Thus, at a time of mounting by the pressure contact method, movement of the semiconductor chip 60 in a planar direction is regulated, and therefore positional displacement of the semiconductor chip 60 in the planar direction is suppressed.

As illustrated in FIGS. 12A to 12C, in the electronic device 1D, the end part 61aa as a part of the end 61a of each of the bumps 61 in the vicinities of both end corner portions 65 in the region along the one side of the semiconductor chip 60 is brought into contact, for example, pressure contact with the upper surface 51a of the pad 51 of the substrate 50. Thus, loads applied to contact portions of the bumps 61 and the pads 51 in the vicinities of both end corner portions 65 or stress occurring in the contact portions is increased, so that pressure contact forces are enhanced. The pressure contact forces are enhanced between the bumps 61 and the pads 51 in the vicinities of the corner portions 65 that tend to be affected by a warp of the substrate 50 and in which the pressure contact forces tend to be consequently relatively low. An increase in resistance or a failure in coupling between the bumps 61 and the pads 51 is therefore suppressed. In addition, the pressure contact forces are made uniform in the contact portion groups of the bumps 61 and the pads 51 in the vicinities of the corner portions 65 and in the other region. The electronic device 1D excellent in coupling quality and coupling reliability between the bumps 61 and the pads 51 is thereby realized.

A sixth embodiment will next be described.

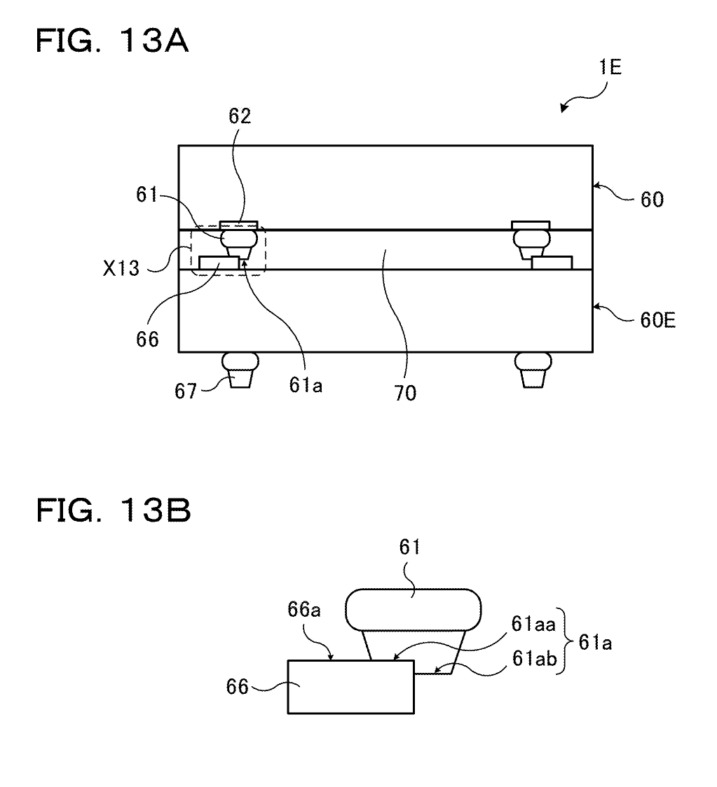

FIGS. 13A and 13B are diagrams illustrating an example of an electronic device according to a sixth embodiment. FIG. 13A is a fragmentary sectional schematic view of the electronic device according to the sixth embodiment. FIG. 13B is an enlarged schematic view of an X13 portion in FIG. 13A.

The electronic device 1E illustrated in FIG. 13A (and FIG. 13B) includes a constitution formed by mounting a semiconductor chip 60 on another semiconductor chip 60E. The semiconductor chip 60E is provided with a pad 66 (terminal) in correspondence with a bump 61 of the mounted semiconductor chip 60.

As with the electronic device 1A described in the foregoing second embodiment, the electronic device 1E is, for example, formed by the pressure contact method. For example, the semiconductor chip 60 is disposed to be opposed to the semiconductor chip 60E above the semiconductor chip 60E provided with an adhesive 70, with the bump 61 of the semiconductor chip 60 aligned with the pad 66 of the semiconductor chip 60E. Pressurization and heating are thereafter performed, and the adhesive 70 is cured.

An end part 61aa as a part of an end 61a of the bump 61 of the semiconductor chip 60 is brought into contact (collision), for example, pressure contact with an upper surface 66a of the pad 66 of the semiconductor chip 60E. An end part 61ab as another part of the end 61a is located on the outside of the pad 66. A relative position, for example, a displacement between the bump 61 of the semiconductor chip 60 and the pad 66 of the semiconductor chip 60E is set according to the example of the relative position between the bump 61 of the semiconductor chip 60 and the pad 51 of the substrate 50 as described in the foregoing second to fifth embodiments.

Thus, also in the mode in which the semiconductor chip 60 is mounted on the semiconductor chip 60E, a part of the end 61a of the bump 61 is brought into pressure contact with the upper surface 66a of the pad 66. Therefore, a load applied to contact portions of the bump 61 and the pad 66 or stress occurring in the contact portions is increased, so that a pressure contact force is enhanced. The electronic device 1E excellent in coupling quality and coupling reliability is thereby realized in which an increase in resistance or a failure in coupling between the bump 61 and the pad 66 is suppressed.

Incidentally, as illustrated in FIG. 13A, for example, a bump 67 (terminal) is disposed on a surface of the semiconductor chip 60E, the surface being on an opposite side from a surface on which the pad 66 is disposed. The bump 67 is used so that the semiconductor chip 60E after the mounting of the semiconductor chip 60 or before the mounting of the semiconductor chip 60 may be mounted on yet another semiconductor chip, or mounted on a substrate 50 as described above. In this case, a relative position, for example, a displacement between the bump 67 and a pad to which to couple the bump 67 may be set according to the example of the relative position between the bump 61 of the semiconductor chip 60 and the pad 51 of the substrate 50 as described in the foregoing second to fifth embodiments from a viewpoint of enhancing a pressure contact force between the bump 67 and the pad to which to couple the bump 67.

In addition, not only the semiconductor chip 60 but also various kinds of semiconductor devices such as a semiconductor package formed by mounting a semiconductor chip on a package substrate may be mounted on the semiconductor chip 60E. Further, various kinds of semiconductor devices such as a semiconductor package may be used in place of the semiconductor chip 60E.

A seventh embodiment will next be described.

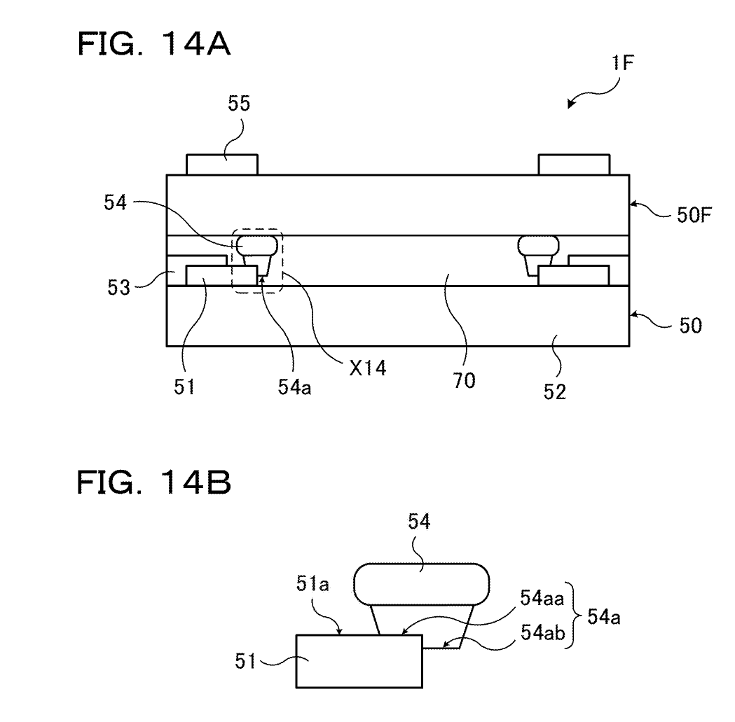

FIGS. 14A and 14B are diagrams illustrating an example of an electronic device according to a seventh embodiment. FIG. 14A is a fragmentary sectional schematic view of the electronic device according to the seventh embodiment. FIG. 14B is an enlarged schematic view of an X14 portion in FIG. 14A.

The electronic device 1F illustrated in FIG. 14A (and FIG. 14B) includes a constitution formed by mounting, on a substrate 50, another substrate 50F. As with the substrate 50, the substrate 50F is various kinds of substrates such as a printed board used as a package substrate or a main substrate and an interposer having a semiconductor or glass as a base material. The substrate 50F is provided with a bump 54 (terminal) in correspondence with a pad 51 of the substrate 50 on which the substrate 50F is mounted.

As with the electronic device 1A described in the foregoing second embodiment, the electronic device 1F is, for example, formed by the pressure contact method. For example, the substrate 50F is disposed to be opposed to the substrate 50 above the substrate 50 provided with an adhesive 70, with the bump 54 of the substrate 50F aligned with the pad 51 of the substrate 50. Pressurization and heating are thereafter performed, and the adhesive 70 is cured.

An end part 54aa as a part of an end 54a of the bump 54 of the substrate 50F is brought into contact (collision), for example, pressure contact with an upper surface 51a of the pad 51 of the substrate 50. An end part 54ab as another part of the end 54a is located on the outside of the pad 51. A relative position, for example, a displacement between the bump 54 of the substrate 50F and the pad 51 of the substrate 50 is set according to the example of the relative position between the bump 61 of the semiconductor chip 60 and the pad 51 of the substrate 50 as described in the foregoing second to fifth embodiments.

Thus, also in the mode in which the substrate 50F is mounted on the substrate 50, a part of the end 54a of the bump 54 is brought into pressure contact with the upper surface 51a of the pad 51. Therefore, a load applied to contact portions of the bump 54 and the pad 51 or stress occurring in the contact portions is increased, so that a pressure contact force is enhanced. The electronic device 1F excellent in coupling quality and coupling reliability is thereby realized in which an increase in resistance or a failure in coupling between the bump 54 and the pad 51 is suppressed.

Incidentally, as illustrated in FIG. 14A, for example, a pad 55 (terminal) is disposed on a surface of the substrate 50F, the surface being on an opposite side from a surface thereof on which the bump 54 is disposed. The pad 55 is used so that yet another substrate may be mounted on the substrate 50F after being mounted on the substrate 50 or before being mounted on the substrate 50, or the semiconductor chip 60, the semiconductor chip 60E, or the like as described above may be mounted on the substrate 50F. In this case, a relative position, for example, a displacement between the pad 55 and a bump to which to couple the pad 55 may be set according to the example of the relative position between the pad 51 of the substrate 50 and the bump 61 of the semiconductor chip 60 as described in the foregoing second to fifth embodiments from a viewpoint of enhancing a pressure contact force between the pad 55 and the bump to which to couple the pad 55.

In the foregoing second to seventh embodiments, taken as an example is coupling between bumps in a peripheral arrangement in which the bumps are arranged along the periphery of one electronic part (the semiconductor chip 60 or the like) and corresponding pads of another electronic part (the substrate 50 or the like). In addition, the above-described method, for example, the method of bringing a part of an end of a bump into pressure contact with an upper surface of a pad is similarly applicable to coupling between one of bumps arranged on one electronic part and a corresponding pad on another electronic part.

An eighth embodiment will next be described.

The electronic devices 1, 1A, 1B, 1C, 1D, 1E, and 1F as described in the foregoing first to seventh embodiments and the like may be incorporated into various kinds of electronic apparatuses. The electronic devices 1, 1A, 1B, 1C, 1D, 1E, 1F, and the like may, for example, be incorporated into various kinds of electronic apparatuses such as a computer (a personal computer, a supercomputer, a server, or the like), a smart phone, a mobile telephone, a tablet terminal, a sensor, a camera, an audio apparatus, a measuring device, an inspecting device, a manufacturing device, and the like.

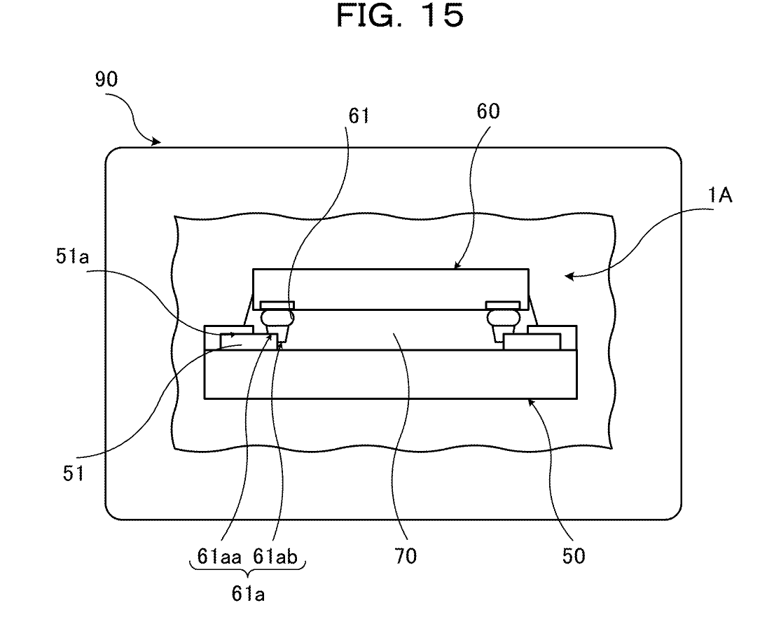

FIG. 15 is a diagram of assistance in explaining an electronic apparatus according to an eighth embodiment. FIG. 15 schematically illustrates an example of an electronic apparatus.

As illustrated in FIG. 15, the electronic device 1A (FIGS. 7A to 7C) as described in the foregoing second embodiment, for example, is incorporated (included) into various kinds of electronic apparatuses 90.

In the electronic device 1A, the end part 61aa as a part of the end 61a of the bump 61 of the semiconductor chip 60 is brought into pressure contact with the upper surface 51a of the pad 51 of the substrate 50. Thus, a load or stress in the contact portions of the bump 61 and the pad 51 is increased, so that the pressure contact force is enhanced. The electronic device 1A excellent in coupling quality and coupling reliability is thereby realized in which an increase in resistance or a failure in coupling between the bump 61 and the pad 51 is suppressed. The various kinds of electronic apparatuses 90 excellent in performance and reliability are realized by incorporating such an electronic device 1A.

Here, an electronic apparatus 90 incorporating the electronic device 1A described in the foregoing second embodiment is illustrated as an example. However, the electronic devices 1, 1B, 1C, 1D, 1E, and 1F described in the foregoing first and third to seventh embodiments and the like may be similarly incorporated into various kinds of electronic apparatuses.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a first electronic part that includes a first terminal;
a second electronic part disposed to be opposed to the first electronic part, the second electronic part that includes a second terminal including a first end part in contact with the first terminal and a second end part located on an outside of the first terminal; and
an adhesive disposed between the first electronic part and the second electronic part, the adhesive maintaining the contact between the first terminal and the first end part by bonding the first electronic part and the second electronic part to each other.

2. The electronic device according to claim 1, wherein
as viewed in plan, an area of the first end part is equal to an area of the second end part or smaller than the area of the second end part.

3. The electronic device according to claim 1, wherein
the second terminal is disposed in a vicinity of a first corner of the second electronic part.

4. The electronic device according to claim 3, wherein
the first electronic part includes a third terminal,
the second electronic part includes a fourth terminal including a third end part in contact with the third terminal and a fourth end part located on an outside of the third terminal, and
the adhesive maintains the contact between the third terminal and the third end part by bonding the first electronic part and the second electronic part to each other.

5. The electronic device according to claim 4, wherein
the second terminal is disposed in a region along a first side of the second electronic part,
the fourth terminal is disposed in a region along a second side of the second electronic part, the second side being opposed to the first side, and
a direction of going from the first end part to the second end part and a direction of going from the third end part to the fourth end part are opposite to each other.

6. The electronic device according to claim 4, wherein
the fourth terminal is disposed in a vicinity of a second corner of the second electronic part, the second corner being different from the first corner.

7. An electronic device manufacturing method comprising:
opposing a first electronic part that includes a first terminal to a second electronic part that includes a second terminal such that a first end part of the second terminal is in contact with the first terminal and a second end part of the second terminal is located on an outside of the first terminal; and
maintaining the contact between the first terminal and the first end part by bonding the first electronic part and the second electronic part to each other by an adhesive disposed between the first electronic part and the second electronic part.

8. An electronic apparatus comprising:
an electronic device;
the electronic device including
a first electronic part that includes a first terminal,
a second electronic part disposed to be opposed to the first electronic part, the second electronic part that includes a second terminal including a first end part in contact with the first terminal and a second end part located on an outside of the first terminal, and
an adhesive disposed between the first electronic part and the second electronic part, the adhesive maintaining the contact between the first terminal and the first end part by bonding the first electronic part and the second electronic part to each other.
